(19) United States
(12) Patent Application Publication
(10) Pub. No.: US 2014/0215805 A1
(43) Pub. Date: Aug. 7, 2014

(54) REMOVABLE CONFORMAL RADIO FREQUENCY SHIELDS

(71) Applicant: QUALCOMM INCORPORATED, San Diego, CA (US)

(72) Inventors: Yang ZHANG, San Diego, CA (US); Jack B. STEENSTRA, San Diego, CA (US)

(73) Assignee: QUALCOMM INCORPORATED, San Diego, CA (US)

(21) Appl. No.: 13/757,811

(22) Filed: Feb. 3, 2013

(51) Int. Cl. H05K 13/00

(52) U.S. Cl. CPC H05K 13/00
USPC 29/593; 264/40.1; 249/66.1

(57) ABSTRACT

A method for manufacturing a removable metalized conformal shield for a circuit substrate having at least one circuit component includes: forming a cast representing the circuit substrate having the at least one circuit component; preparing a metalized conformal shield using the cast; applying the metalized conformal shield to the circuit substrate; measuring an output of the circuit component of the circuit substrate; removing the metalized conformal shield from the circuit substrate; and adjusting the circuit component based on the measured output.

### BACKGROUND

1. Field

The disclosure relates generally to the field of radio frequency (RF) conformal shields, and, in particular, to removable RF conformal shields and methods of manufacturing such.

2. Background

Radio frequency (RF) shielding is indispensable in wireless radios to eliminate electromagnetic interference (EMI) and achieve electromagnetic compatibility. Traditional RF shielding employs metal cans over electronic components (e.g., electronic components of a printed circuit board (PCB)) to protect or shield the electronic components. The metal cans usually have holes or slots for heat ventilation during surface mount technology process. These openings compromise the shielding efficacy of the metal cans. In addition, because the shield cans are made of sheet metal, the tolerance and material thickness of the shield cans require a certain height between the tallest electronic component of the electronic shielded components and the shield can.

Metalized conformal shielding is another RF-shielding method. A metalized conformal shield for protecting electronic components is generally made by an injection-molding or printing molding process followed by a metal-coating/sputtering process. In particular, first, an insulating layer, such as a plastic material, epoxy, or the like, is injection molded over the electronic components to create a conformal shield molding. Then, a metal layer is coated or spattered over the conformal shield molding to form the metalized conformal shield. Such a process provides very precise dimensions and allows the conformal shield to be at the same height of the tallest electronic component of the electronic components. As such, metalized conformal shielding can provide a smaller height constraint than the traditional metal cans. In addition, the thickness of the metal coating is relatively small (e.g., 1 μm or 2 μm, etc.) and thus has virtually no impact to the overall height of a circuit to which the metalized conformal shield is applied.

Before receiving the metalized conformal shield, the electrical components (e.g., RF circuit) are adjusted to provide a desired output. However, after the metalized conformal shield is applied over the electronic components, performance of the RF circuit is affected by the metalized conformal shield because the metalized conformal shield alters the parasitic parameters surrounding the electronic components. Such a change in performance may not be within a desirable tolerance for the device in which the RF circuit is to be implemented. However, the metalized conformal shield cannot be removed to gain access to the electronic components to re-adjust the RF circuit. One prior art method for overcoming this issue is to pre-offset the RF performance in anticipation of the changes caused by the molding materials of the metalized conformal shield. This iterative process is time consuming and costly. Moreover, predicting the specific impact of the molding materials to the RF circuit is difficult.

### SUMMARY

A method for manufacturing a removable metalized conformal shield for a circuit substrate having at least one circuit component includes, but is not limited to any one or combination of: (i) forming a cast representing the circuit substrate having the at least one circuit component; (ii) preparing a metalized conformal shield using the cast; (iii) applying the metalized conformal shield to the circuit substrate; (iv) measuring an output of the circuit component of the circuit substrate; (v) removing the metalized conformal shield from the circuit substrate; and (vi) adjusting the circuit component based on the measured output.

In various embodiments, the method further includes re-applying the metalized conformal shield to the circuit substrate after adjusting the circuit component based on the measured output.

In some embodiments, after re-applying the metalized conformal shield, the method further includes: re-measuring the output of the circuit component of the circuit substrate; re-removing the metalized conformal shield from the circuit substrate; and re-adjusting the circuit component based on the measured output.

In various embodiments, the method further includes adjusting the circuit component of the circuit substrate to provide a specified output before applying the metalized conformal shield to the circuit substrate.

In some embodiments, after removing the metalized conformal shield, the circuit component is adjusted based on the measured output and the specified output.

In some embodiments, the measured output corresponds to the specified output.

In various embodiments, the metalized conformal shield comprises a conformal shield made of an insulating layer and a metallic layer disposed over the conformal shield.

In some embodiments, the metallic layer is electrically coupled with contacts of the circuit substrate when the metalized conformal shield is applied to the circuit substrate.

In various embodiments, preparing a metalized conformal shield using the cast includes: depositing a release layer on a surface of the cast; depositing an insulating layer over the release layer to form a conformal shield; and depositing a metallic layer over the conformal shield to form the metalized conformal shield.

In various embodiments, preparing a metalized conformal shield using the cast includes: depositing an insulating layer over a surface of the cast to form a conformal shield; and depositing a metallic layer over the conformal shield to form the metalized conformal shield.

In various embodiments, the circuit substrate having the at least one circuit component includes a printed circuit board (PCB).

In various embodiments, forming a cast representing the circuit substrate having the at least one circuit component includes: assembling the at least one circuit component on the circuit substrate to provide an assembled circuit; and forming a cast based on the assembled circuit.

In various embodiments, forming a cast representing the circuit substrate having the at least one circuit component includes: forming a cast representing the circuit substrate having the at least one circuit component based on specifications of the circuit substrate and the least one circuit component.

In some embodiments, forming a cast representing the circuit substrate having the at least one circuit component further includes assembling the at least one circuit component on the circuit substrate to provide an assembled circuit. The metalized conformal shield is prepared using the cast before the assembled circuit is provided

In various embodiments, the method further includes: preparing a second metalized conformal shield using the cast; and applying the second metalized conformal shield to the circuit substrate after adjusting the circuit component based on the measured output.

In some embodiments, after applying the second metalized conformal shield, the method further including: re-measuring the output of the circuit component of the circuit substrate; removing the second metalized conformal shield from the circuit substrate; and re-adjusting the circuit component based on the measured output.

An apparatus for manufacturing a removable metalized conformal shield for a circuit substrate having at least one circuit component, includes, but is not limited to any one or combination of: means for making an imprint of the circuit substrate having the at least one circuit component; means for forming a mold based on the imprint; means for preparing a metalized conformal shield using the mold; means for applying the metalized conformal shield to the circuit substrate; means for measuring an output of the circuit component of the circuit substrate; means for removing the metalized conformal shield from the circuit substrate; and means for adjusting the circuit component based on the measured output.

A method for manufacturing a removable metalized conformal shield for a circuit substrate having at least one circuit component includes but is not limited to any one or combination of: (i) forming a cast representing the circuit substrate having the at least one circuit component; (ii) depositing an insulating layer over a surface of the cast to form a conformal shield; and (iii) depositing a metallic layer over the conformal shield to form the metalized conformal shield.

In various embodiments, the method further includes removing the metalized conformal shield from the surface of the cast.

In various embodiments, the cast is formed of a material that does not adhere to the insulating layer.

In various embodiments, the cast is formed of a material comprising stainless steel.

In various embodiments, the cast is formed to compensate for a tolerance range of each circuit component of the at least one circuit component.

In various embodiments, the method further includes depositing a release layer over the surface of the cast. The insulating layer is deposited over the release layer to form the conformal shield.

In some embodiments, the method further includes removing the metalized conformal shield from the release layer on the surface of the cast.

In some embodiments, the method further includes removing the conformal shield from the release layer on the surface of the cast before the metallic layer is deposited over the conformal shield to form the metalized conformal shield.

In some embodiments, a thickness of the metallic layer is greater than a thickness of the release layer.

In various embodiments, a maximum thickness of the conformal shield is substantially equal to a height of a tallest circuit component of the at least one circuit component from a surface of the circuit substrate.

In various embodiments, a top surface of the conformal shield is flush with a top surface of a tallest circuit component of the at least one circuit component.

In various embodiments, the method further includes removing the conformal shield from the surface of the cast before the metallic layer is deposited over the conformal shield to form the metalized conformal shield.

In various embodiments, the metallic layer is electrically coupled with contacts of the circuit substrate when the metalized conformal shield is applied to the circuit substrate.

In various embodiments, the method further includes forming a plurality of openings in the conformal shield at one or more specified areas, the specified areas corresponding to contact pads on the circuit substrate.

In some embodiments, forming the plurality of openings in the conformal shield includes ablating the insulating layer of the conformal shield at the specified areas.

In some embodiments, forming the plurality of openings in the conformal shield includes: applying a mask layer over portions of the release layer before depositing the insulating layer, the portions corresponding to the contact pads on the circuit substrate; and removing the masking layer after depositing the insulating layer.

In some embodiments, the method further includes depositing at least some of the metallic layer in the plurality of openings in the conformal shield to electrically couple with the contact pads of the circuit substrate when the metalized conformal shield is applied to the circuit substrate.

In further embodiments, at least one of the plurality of openings in which the at least some metallic layer is deposited corresponds to one of the contact pads provided between at least two of the circuit components.

### BRIEF DESCRIPTION OF THE DRAWINGS

FIG. 1 is a cross-section view of an assembled circuit according to various embodiments of the disclosure.

FIG. 2 is a cross-section view of a shielded circuit having a removable metalized conformal shield according to various embodiments of the disclosure.

FIGS. 3A-3B illustrate a method of manufacturing a shielded circuit having a removable metalized conformal shield according to various embodiments of the disclosure.

FIGS. 4A-4E illustrate various stages of forming a metalized conformal shield according to various embodiments of the disclosure.

FIGS. 5A-5B illustrate a method of preparing a metalized conformal shield according to various embodiments of the disclosure.

FIGS. 6A-6D illustrate various stages of forming a metalized conformal shield according to various embodiments of the disclosure.

### DETAILED DESCRIPTION

According to various embodiments, a metalized conformal shield is configured to be removable from electronic (circuit) components of a device. As a result the metalized conformal shield can be applied over the electronic components freely and repeatedly so that the RF performance of the device can be optimized very quickly, thus reducing turn-around time significantly (e.g., from months to a few days).

The metalized conformal shield includes a conformal shield formed to conform or adapt to the shape of an item to be shielded. In particular embodiments, the conformal shield is implemented with (e.g., conformed or adapted to the shape of) a printed circuit board assembly (PCBA). In other embodiments, the conformal shield may be used to shield other electrical systems and electronic devices. A metal layer or coating is applied to the conformal shield to form the metalized conformal shield.

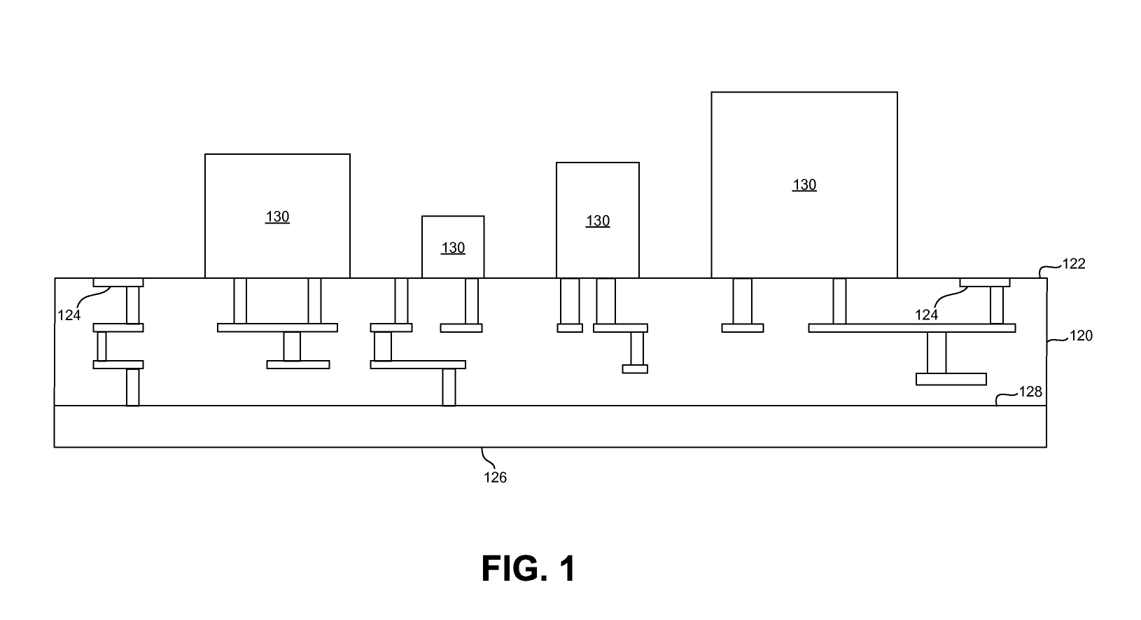

FIG. 1 illustrates an assembled circuit, such as a printed circuit board assembly (PCBA) 125. The assembled circuit or PCBA 125 may include a circuit substrate 120, such as a printed circuit board (PCB), flex PCB, or rigid flex PCB, and one or more circuit components (electronic components) 130 (130a-130d) assembled or otherwise disposed on the circuit substrate 120.

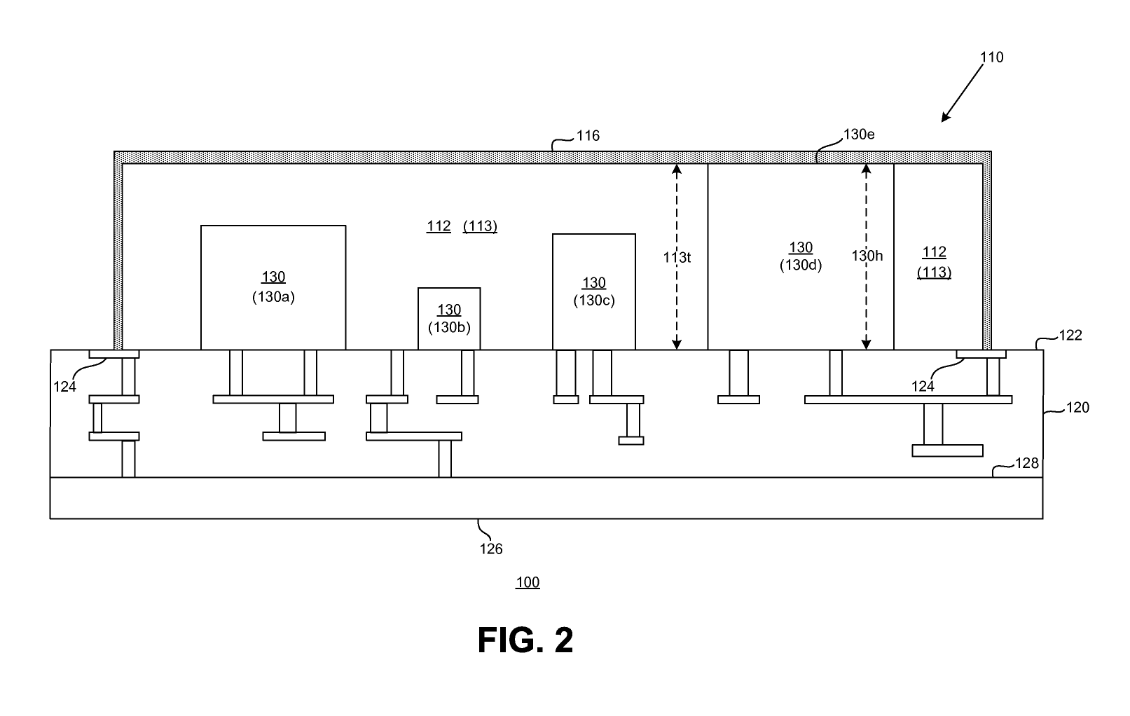

FIG. 2 illustrates a shielded circuit 100 that includes a metalized conformal shield 110 applied to the PCBA 125. The metalized conformal shield 110 is disposed on the circuit substrate 120 and the circuit components 130 to generally conform about the circuit components 130 and at least a portion of the circuit substrate 120. The resulting structure is a substantially enclosed shielded circuit 100, which provides shielding to the circuit components 130. The metalized conformal shield 110 provides protection to the circuit components 130 from external-sourced interfering elements. That is, the metalized conformal shield 110 protects the circuit components 130 from radio frequency (RF) interference, electromagnetic (EM) interference, electrostatic discharge, environmental elements (e.g., moisture, dust, etc.), and/or the like. In various embodiments, the metalized conformal shield 110 generally conforms to (e.g., fit to) each circuit component 130 such that each of the circuit components 130 is individually protected and shielded from potential interference from the other circuit components 130 of the shielded circuit 100.

The metalized conformal shield 110 includes a conformal shield 113 formed from a conformable material that can be adapted to the shape of the circuit substrate 120 and the circuit components 130 (e.g., resistors, integrated circuit packages, capacitors, inductors, etc.) disposed on the circuit substrate 120. The conformal shield 113 includes one or more insulating layer(s) or coating(s) 112 (i.e., electrically insulating layer) that is positioned adjacent to and formed over a top surface 122 of the circuit substrate 120 and the circuit components 130 positioned on the circuit substrate 120. The insulating layer 112 is positioned over (e.g., in contact with) the circuit components 130 to help protect the circuit components 130 and other portions of the circuit substrate 120 from electrical shorts and the like. The insulating layer 112 can be formed of any electrically insulating material that can be made to conform to the shape of the circuit components 130 and the circuit substrate 120. The material of the insulating layer 112 may include, but is not limited to, any one or combination of, an epoxy coating, a silicone-based coating, a polymer (e.g., an ultraviolet (UV) curable polymer), a resin, and/or the like. The insulating layer 112 may be deposited in any suitable manner, such as via injection molding, printing molding, a spray coating process, a dip coating process, and/or the like.

In particular embodiments, the insulating layer 112 (conformal shield 113) has a thickness 113t substantially equal to a height 130h of the tallest circuit component 130 (130d in FIG. 2) from the top surface 122 of the circuit substrate 120. In such embodiments, for instance, the insulating layer 112 is not provided over a top surface 130e of the tallest circuit component 130d.

A metallic layer 116 is deposited over the conformal shield 113 to form the metalized conformal shield 110. The metallic layer 116 may be made of an electrically conductive metal (e.g., copper, silver, nickel, etc.) to provide RF and EM shielding to the shielded circuit 100. In some embodiments, the metallic layer 116 may be formed of multiple layers. The metallic layer 116 may be applied to or otherwise provided on the conformal shield 113 via metal deposition or any other suitable method. For instance, the metallic layer 116 may be applied (but is not limited to) via a sputtering or evaporative coating process, electroless plating process, spray painting with metallic paint, silver-paste printing, and/or the like. In particular embodiments, the metallic layer 116 is deposited on the conformal shield 113 such that the metallic layer 116 has at least a minimal thickness (e.g., 1-5 μm) to provide uniform and complete metal coverage. In addition to being provided on the conformal shield 113, the metallic layer 116 may be provided over the top surface 130e of the tallest circuit component 130d. As such, the metallic layer 116 may extend continuously across the conformal shield 113 and the top surface 130 of the tallest circuit component 130d.

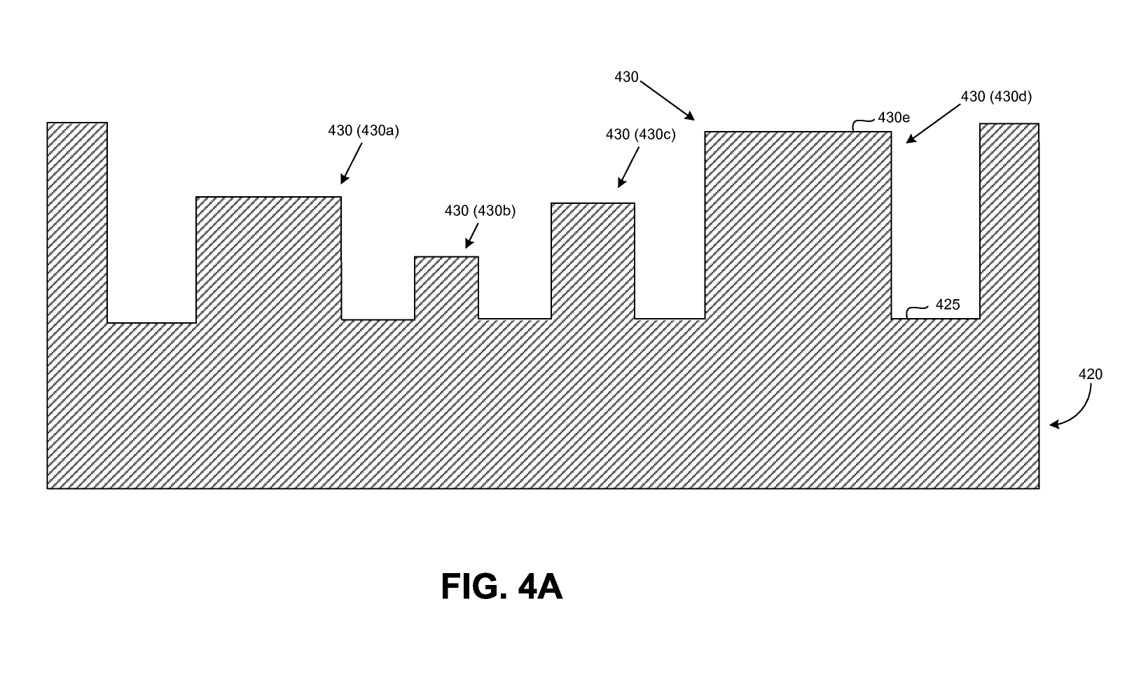

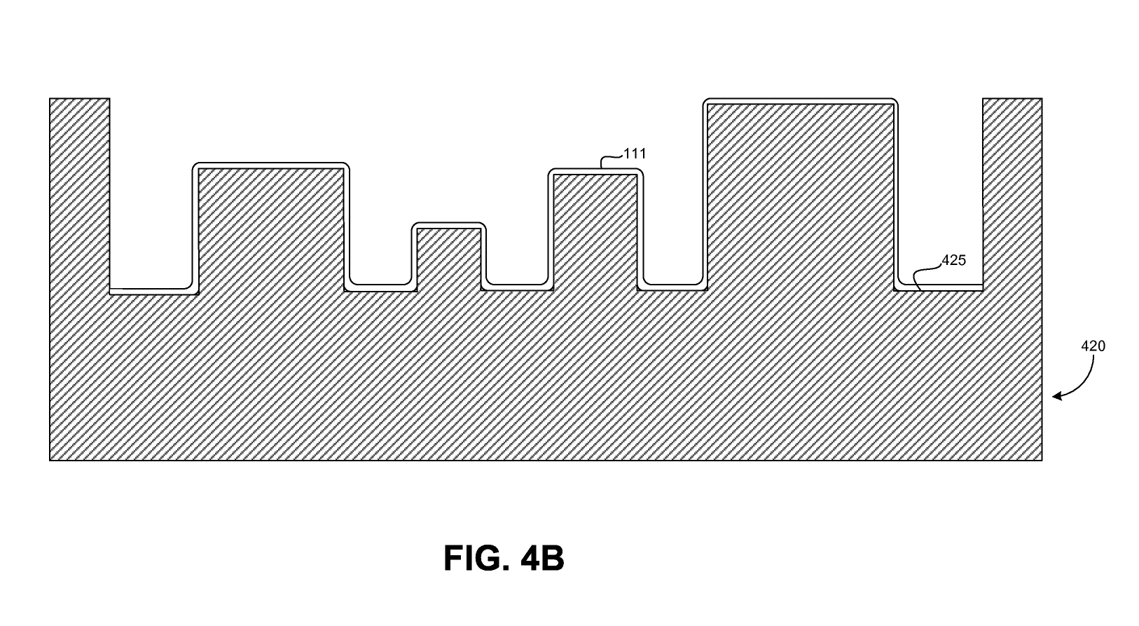

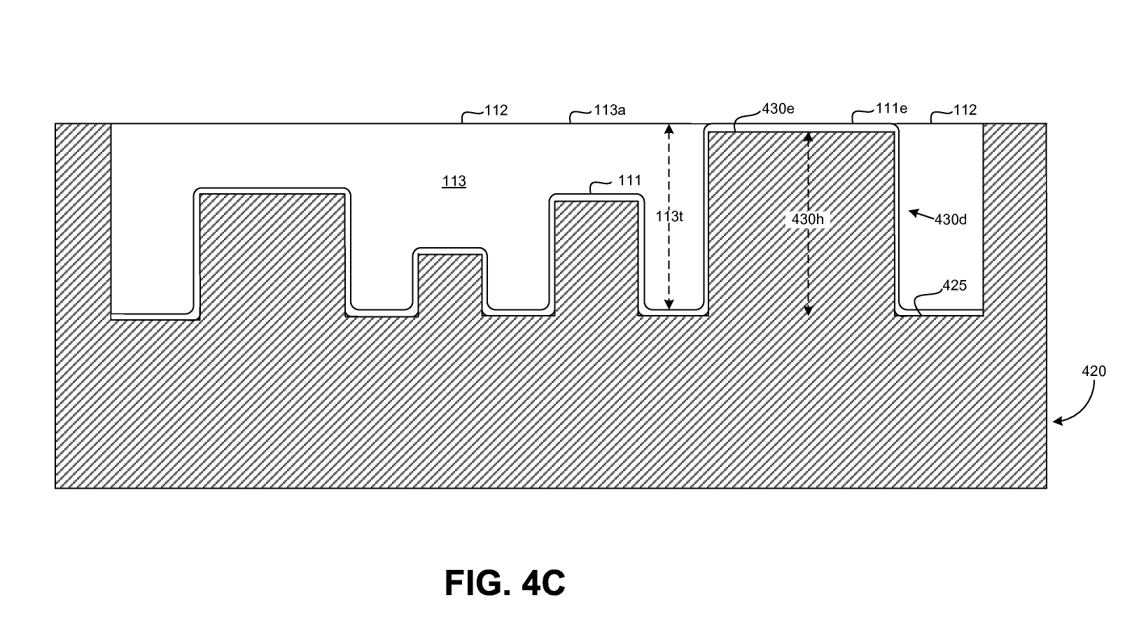

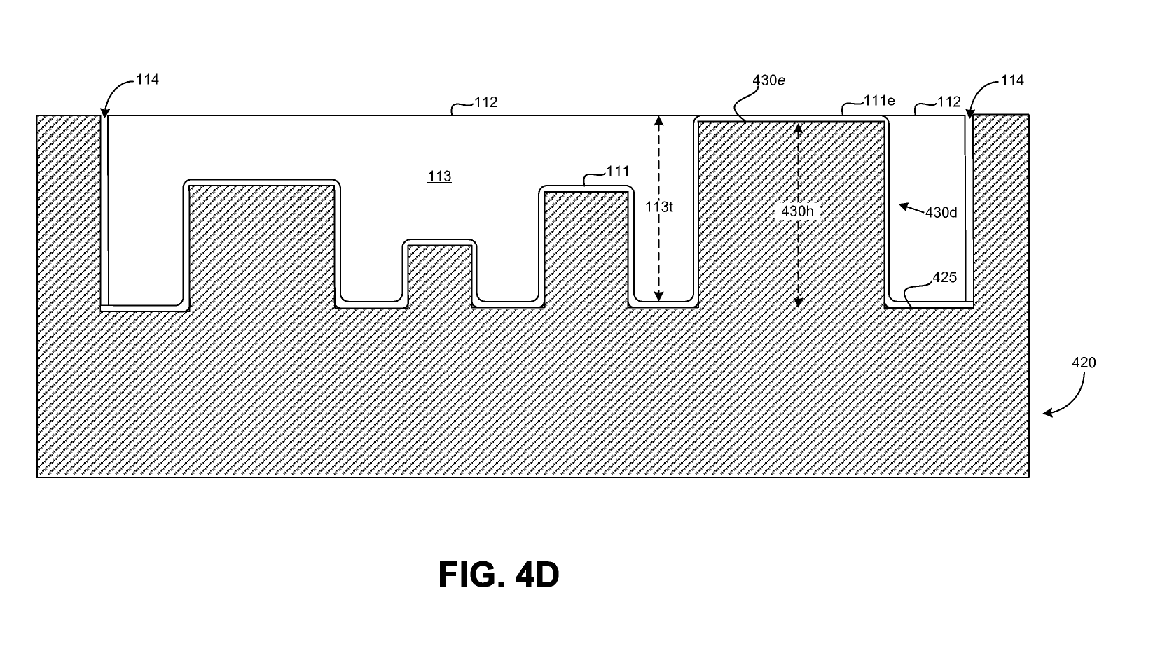

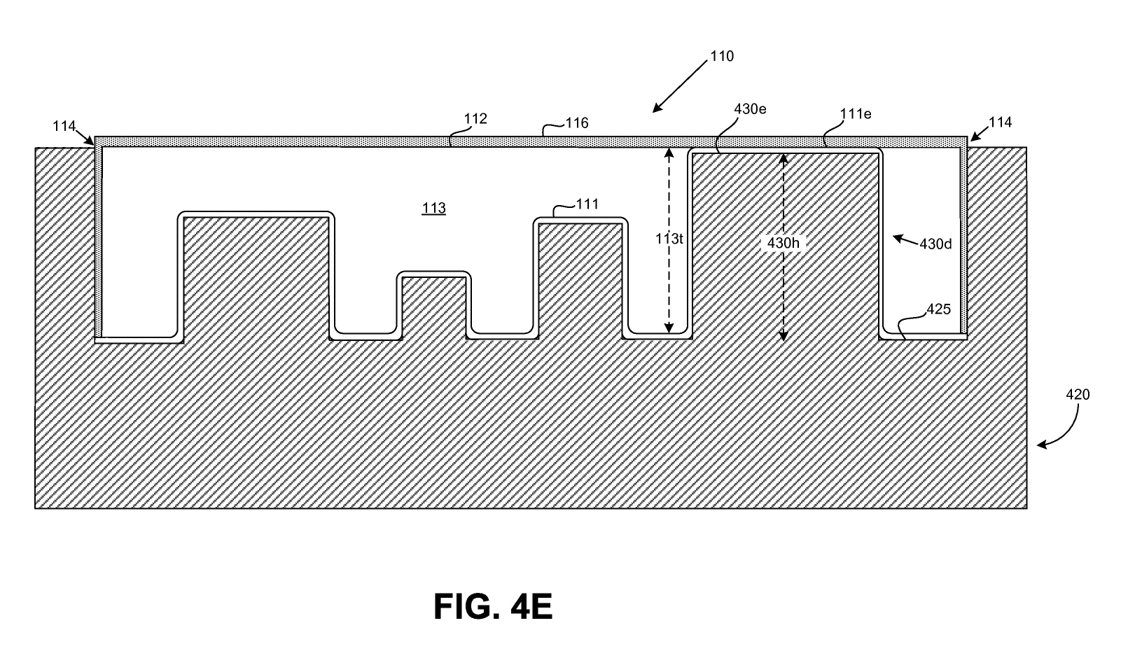

In some embodiments, a plurality of openings (e.g., 114 in FIG. 4E) may be formed in the conformal shield 113 to expose contact pads 124 located on the circuit substrate 120. The exposed contact pads 124 electrically couple the metalized conformal shield 110 to a ground plane 126 of the circuit substrate 120. The ground plane 126 may be on a back surface 128 of the circuit substrate 120. Thus, for instance, when depositing the metallic layer 116 on the conformal shield 113, the metallic layer 116 may also be deposited in the openings 114 such that an electrical connection between the metallic layer 116 and the contact pads 124 may be formed when the metalized conformal shield 110 is applied to the circuit substrate 120. The electrical connection between the metallic layer 116 and the contact pads 124 electrically couples the metalized conformal shield 110 to the circuit substrate 120.

Although not shown, in some embodiments, the contact pads 124 may be located along any position along the circuit substrate 120, such as in between (at least) two of the circuit components 130 (e.g., 130b and 130c), or otherwise be located away from an edge of the circuit substrate 120. In such cases, a corresponding one of the openings 114 may be provided in the conformal shield 113 between areas corresponding to the two circuit components 130 such that the metallic layer 116 can be provided within such opening to form a shielding wall (compartment wall) within the conformal shield 113 to separate the two circuit components 130 into respective compartments.

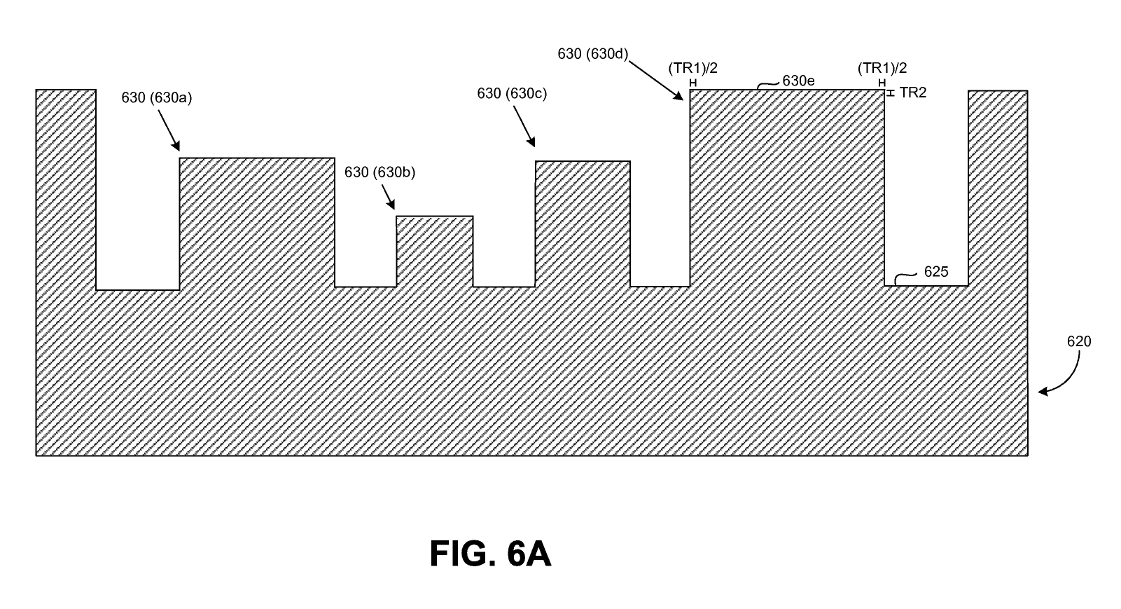

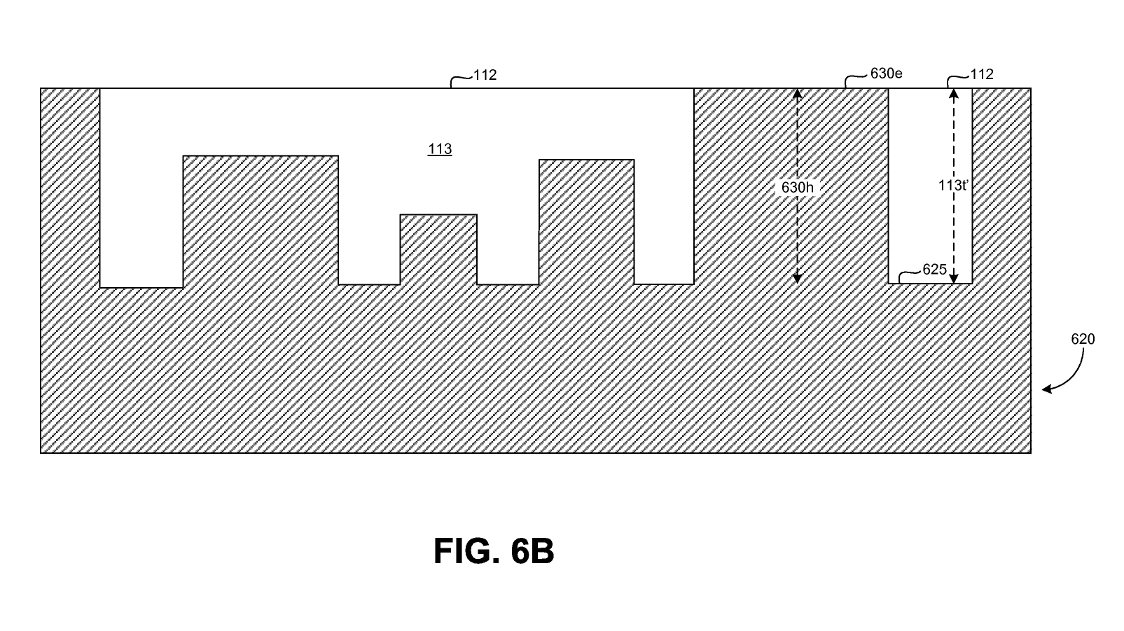

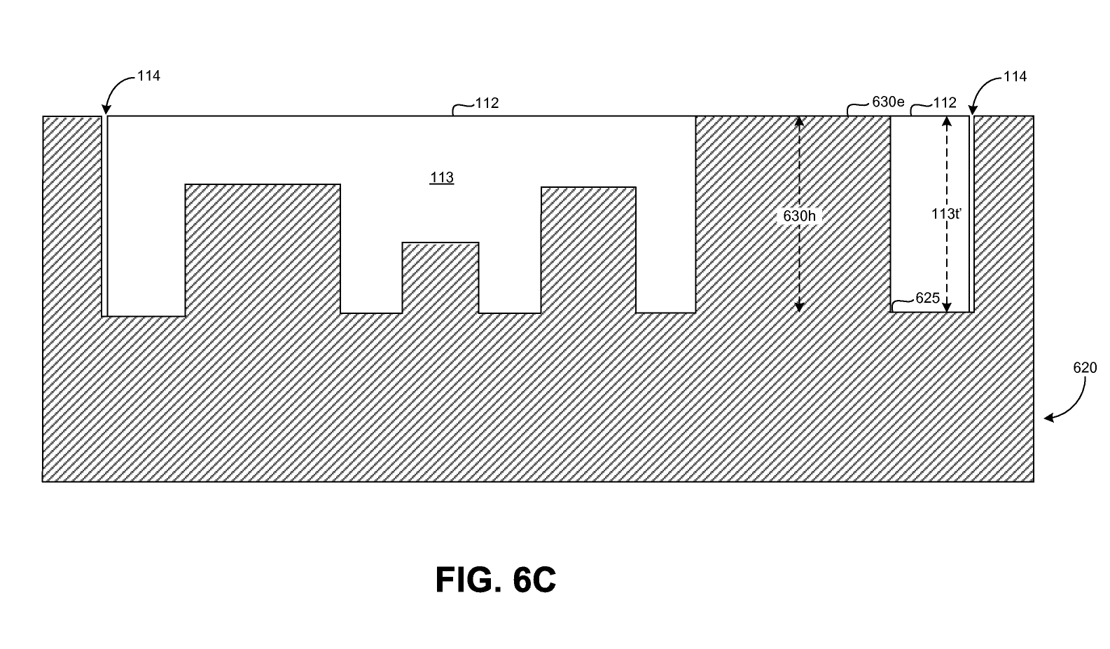

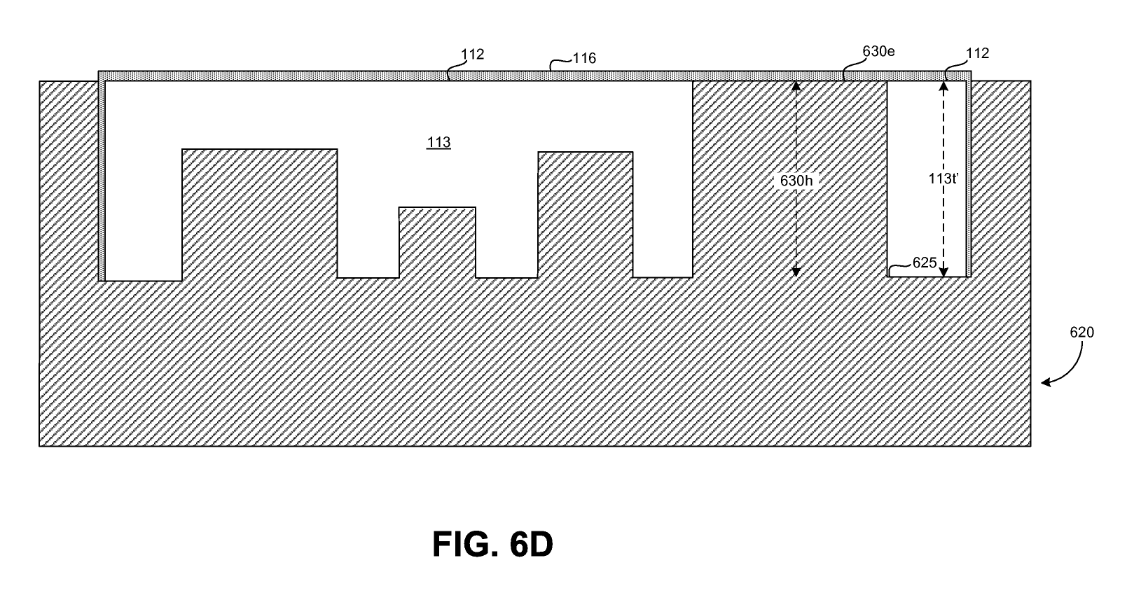

In various embodiments, the metalized conformal shield 110 is formed directly on the circuit substrate 120. In other embodiments, such as (but not limited to) described in the disclosure, the metalized conformal shield 110 is formed separately, for example in a cast (e.g., 420 in FIG. 4; 620 in FIG. 6) from the circuit substrate 120.

In embodiments in which the metalized conformal shield 110 is formed separately from the circuit substrate 120, the metalized conformal shield 110 may be applied on (e.g., attached to) the circuit substrate 120 to form the shielded circuit 100 (e.g., as shown in FIG. 2), the shielded circuit 100 can be inserted into the end product (e.g., a mobile device) and tested to determine if the shield circuit 100, such as one or more of the circuit components 130, is functioning properly (e.g., the one or more circuit components 130 provide a desired output). According to various embodiments, because the metalized conformal shield 110 is removable from the circuit substrate 120, if the shielded circuit 100 is not functioning properly or otherwise needs to be adjusted, the shielded circuit 100 can be removed from the mobile device, and the metalized conformal shield 110 can be removed to adjust the shielded circuit 100 (e.g., one or more of the components 130). As a result, the metalized conformal shield 110 allows for testing of the shielded circuit 100 after application of the metalized conformal shield 110 on the circuit substrate 120. Accordingly, in various embodiments, the metalized conformal shield 110 can be re-applied on the circuit substrate 120 to re-test the shielded circuit 100.

According to various embodiments, after the shielded circuit 100 is adjusted to meet all required specifications (e.g., to provide the desired output(s)), the metalized conformal shield 110 may be removed from the circuit assembly 125 and the circuit assembly 125 may be encapsulated with a non-removable conformal shield. Thus, in such embodiments, the removal able metalized conformal shield 110 is only used during a development (and testing) stage of a product, and is not used in the final product.

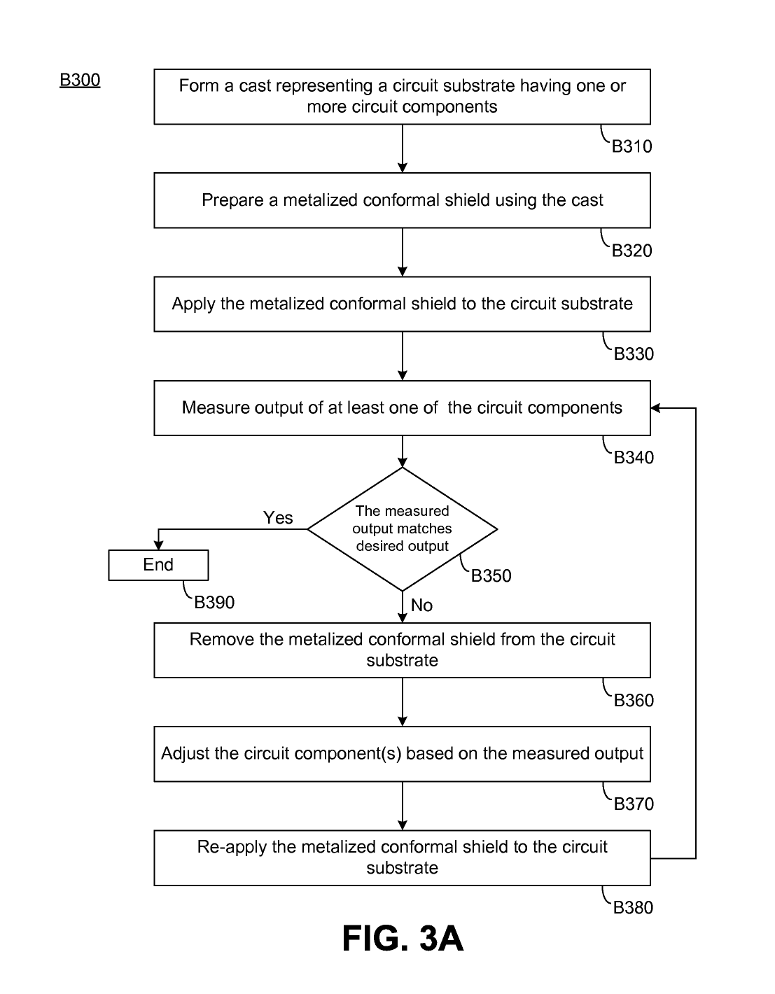

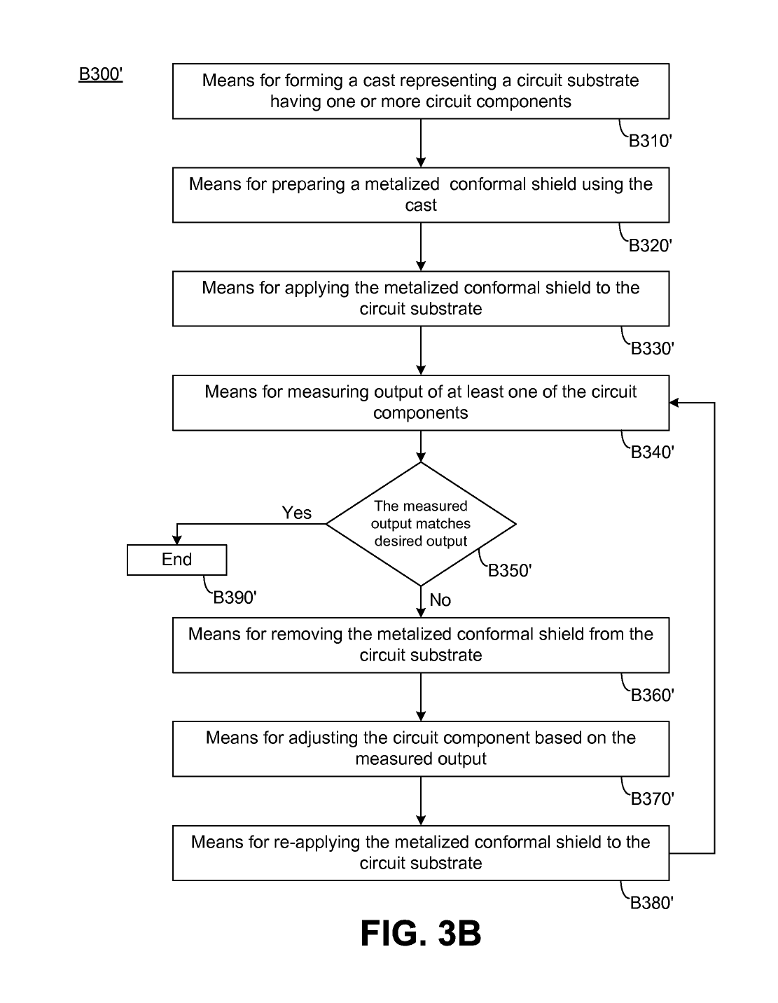

FIG. 3A illustrates a method B300 of manufacturing a shielded circuit (e.g., 100 in FIG. 2) having a removable metalized conformal shield (e.g., 110 in FIG. 2) according to various embodiments of the disclosure. With reference to FIGS. 1-3A, the removable metalized conformal shield 110 may be implemented with a circuit substrate (e.g., 120) having one or a plurality of circuit components (e.g., 130; 130a-130d). In some embodiments, one or more of the circuit components 130 may be adjusted prior to formation of the shielded circuit 100 (e.g., prior to formation of the metalized conformal shield 110 and/or application of the metalized conformal shield 110 to the circuit substrate 120) to provide a specified output. The specified output, for example, may provide a certain output (or an output within a certain range) when the circuit components 130 are shielded by the metalized conformal shield 110 (i.e., the metalized conformal shield 110 is applied to the circuit substrate 120). The circuit components 130 may be adjusted to provide the specified output, for example, based on simulation, intuition, and/or the like. In other embodiments, the one or more circuit components 130 are adjusted at other suitable times, or are not adjusted prior to formation of the shielded circuit 100.

At block B310, a cast 420 representing the circuit substrate 120 and the circuit component(s) 130 (PCBA 125) may be formed (e.g., 420 in FIG. 4A; 620 in FIG. 6A). The portions 430a-430d of the cast 420 may correspond to the circuit components 130a-130d, respectively.

At block B320, the metalized conformal shield 110 may be prepared using the cast 420, for example as described (but not limited to) in the disclosure.

With reference to FIGS. 1-3A, at block B340, the metalized conformal shield 110 may be attached or otherwise applied to the circuit substrate 120 (and the circuit components 130) to form the shielded circuit 100 (e.g., FIG. 2).

After forming the shielded circuit 100, the shielded circuit 100 may be tested to determine whether an output of one or more of the circuit components 130 of the shielded circuit 100 is a desired output (e.g., the output is within an acceptable range). In particular embodiments, the shielded circuit 100 may be installed in a mobile device or other end product in which the shielded circuit 100 is to be used, and then tested in the end product.

For instance, at block B340, an output of one (or more) of the circuit components (e.g., 130a) of the shielded circuit 110 (before or after being installed in the end product in which the shielded circuit 110 is to be used) may be measured. An output of one or more of the circuit components 130b-130d may also be measured.

If the output of the circuit component 130a does not match the desired output or otherwise is not within an acceptable range of values (block B350: No), then at block B360, the metalized conformal shield 110 may be removed from the circuit substrate 120 and the circuit components 130. Accordingly, at block B370, the circuit component 130a that provided the undesired output may be re-adjusted. In particular embodiments, the circuit component 130a may be re-adjusted based on the measured output. For example, if the measured output exceeds the desired output or range, parameters of the circuit component 130a may be adjusted to reduce the output when shielded by the metalized conformal shield 116. After re-adjusting the circuit component 130a, at block B380, the (same) metalized conformal shield 110 can be re-applied to the circuit substrate 120 and the circuit components 130 to re-form the shielded circuit 100. In other embodiments, a new or different metalized conformal shield 110 (e.g., prepared via the cast as at block B320) may be applied to the circuit substrate 120 and the circuit components 130 to re-form the shielded circuit 100. Blocks B340-B380 may be repeated until the output of the circuit component 130a (and any other circuit components 130b-130d) match the desired output or is otherwise within an acceptable range of values.

If the output of the circuit component 130a matches the desired output or is otherwise within an acceptable range of values (block B350: Yes), then at block B390, the method B300 may be complete (i.e., the metalized conformal shield 110 need not be removed and the circuit component 130a re-adjusted).

The method B300 described in FIG. 3A above may be performed by various hardware and/or software component(s) and/or module(s) corresponding to the means-plus-function blocks B300′ illustrated in FIG. 3B. In other words, one or more of blocks B310 through B390 illustrated in FIG. 3A may correspond to one or more of means-plus-function blocks B310′ through B390′ illustrated in FIG. 3B.

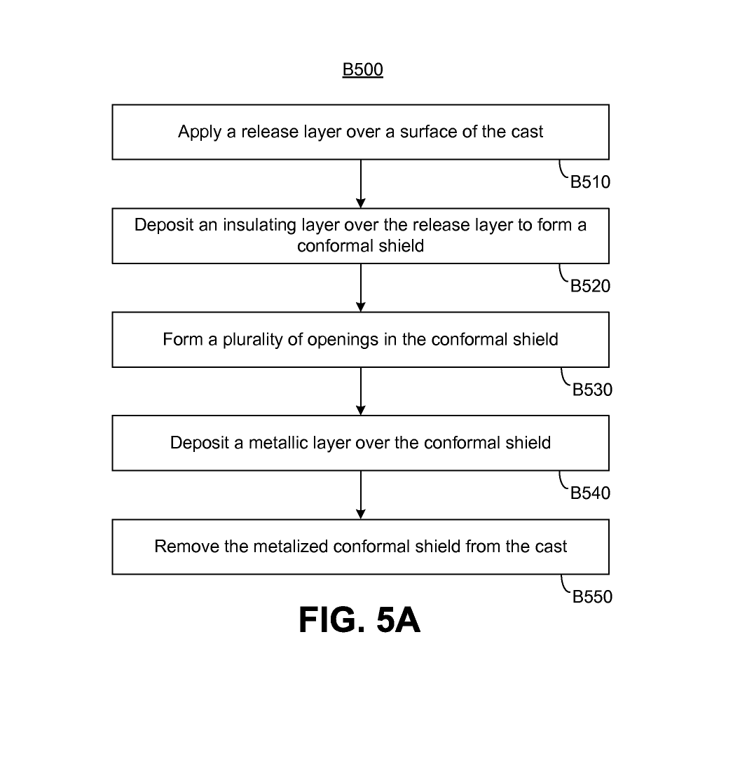

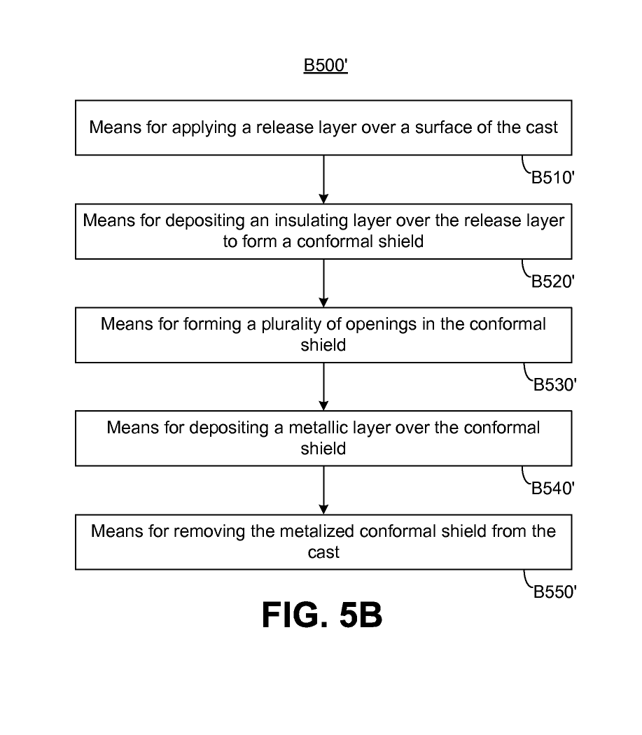

FIG. 5 illustrates a method B500 of preparing a metalized conformal shield (e.g., 110 in FIG. 2) according to various embodiments of the disclosure. FIGS. 4A-4E illustrate various stages of preparing the metalized conformal shield 110. With reference to FIGS. 1-5, at block B510, a release layer (e.g., 111) may be applied over the surface 425 of the cast 420 (e.g., FIG. 4B). As described, the release layer 111 may facilitate removal of the metalized conformal shield 110 from the cast 420 after completion of the metalized conformal shield 110. In particular, the release layer 111 may facilitate removal of the conformal shield 113 from a surface of the release layer 111. The release layer 111 may be made of any suitable material that minimizes adhesion of the metalized conformal shield 110 to the cast 420 (or the release layer 111, itself), and thus facilitate removal of the metalized conformal shield 110 from the cast 420.

In particular embodiments, the release layer 111 may compensate for any differences between circuit substrates and/or circuit components 130 (but are otherwise within specified tolerances), for example, due to differences in size (in any dimension(s)) and/or positioning of the circuit components 130. For example, a circuit component on a first circuit substrate may be positioned 2 μm further away from an edge than a same circuit component on a second circuit substrate. Accordingly, by using the release layer 111, a metalized conformal shield 110 for each of the first circuit substrate and the second circuit substrate may be formed with a cast based on the first circuit substrate.

At block B520, the conformal shield 113 may be formed in any suitable manner, such as (but not limited to) discussed in the disclosure. For example, the conformal shield 113 may be formed from a conformable material that can be adapted to the shape of the cast 420. The conformal shield 113 may include one or more insulating layer(s) or coating(s) (e.g., 112) (i.e., electrically insulating layer) deposited or otherwise provided on or in the cast 420, for instance, over the release layer 111 (e.g., FIG. 4C).

The insulating layer 112 can be formed of any electrically insulating material that can be made to conform to the shape of the cast 420. The insulating material may include, but is not limited to, any one or combination of an epoxy coating, a silicone-based coating, a polymer (e.g., an ultraviolet (UV) curable polymer), a resin, thermoplastic material, and/or the like. The insulating layer 112 may be deposited into the cast 420 or otherwise provided in any suitable manner, such via injection molding, printing molding, a spray coating process, a dip coating process, and/or the like.

In particular embodiments, the insulating layer 112 (conformal shield 113) has a maximum thickness 113t such that a top surface 113a of the conformal shield 113 may be flush with a top surface 111e of the release layer 111 that is provided on the portion 430d (of the cast 420) that corresponds to the tallest circuit component (130d in FIGS. 1-2). In such embodiments, for instance, the insulating layer 112 is not provided over the top surface 111e of the release layer 111 that is provided on the portion 430d of the cast 420. Also, in such embodiments, the maximum thickness 113t may be substantially equal to a height 430h of the portion 430d (of the cast 420) (i.e., the maximum thickness is substantially equal to a distance from a top surface 430e of the portion 430d to the top surface 425, which corresponds to the top surface 122 of the circuit substrate 120, of the cast 420). As such, because the height 430h of the portion 430d corresponds to the height 130h of the tallest circuit component 130d, the maximum thickness 113t may be substantially equal to the height 130h of the tallest circuit component 130d. In addition, in such embodiments a combined thickness of the maximum thickness 113t and a thicknesses of the release layer 111 (e.g., less than 10 μm) may be substantially equally to a combined thickness of the height 430h and a thickness of the release layer 111 on the surface 430. Throughout various embodiments, substantially equal may be defined as within 0-10 μm.

At block B530, a plurality of openings (e.g., 114) may be formed in the conformal shield 113 to correspond to areas at which the contact pads 124 are located on the circuit substrate 120 (e.g., FIG. 4D) (when the metalized conformal shield 110 is applied to the circuit substrate 120). The exposed contact pads 124 electrically couple the metalized conformal shield 110 to a ground plane 126 of the circuit substrate 120 when the metalized conformal shield 110 is applied to the circuit substrate 120.

Although not shown, in some embodiments, the contact pads 124 may be located along any position along the circuit substrate 120, such as in between (at least) two of the circuit components 130 (e.g., 130b and 130c), or otherwise be located away from an edge of the circuit substrate 120. In such cases, a corresponding one of the openings 114 may be provided in the conformal shield 113 between areas corresponding to the two circuit components 130 such that the metallic layer 116 can be provided within such opening to form a shielding wall (compartment wall) within the conformal shield 113 to separate the two circuit components 130 into respective compartments.

The openings 114 may be formed in any suitable manner, such as (but not limited to) via laser ablation (e.g., directing a laser to specified areas on the conformal shield 113 corresponding to the contact pads 124 to ablate any insulating material positioned in the specified areas), a masking layer (not shown) (e.g., applying the masking layer over areas of the release layer 111 corresponding to the contact pads 124 before depositing the insulating layer 112 into the cast 420, and then removing the masking layer after depositing the insulating layer 112), and/or the like.

At block B540, a metallic layer (e.g., 116) may be deposited over the conformal shield 113 to form the metalized conformal shield 110, for instance, after the insulating layer 112 has been allowed to cure and, further for instance, after formation of the openings 114 (e.g., FIG. 4E). The metallic layer 116 may also be deposited over the top surface 430e of the portion 430d (which corresponds to the tallest circuit component 130d). As such, the metallic layer 116 may extend continuously across the conformal shield 113 and the top surface 430e of the portion 430d. In addition to being deposited over the conformal shield 113, the metallic layer 116 may also be deposited in the openings 114, thus coating side surfaces of the conformal shield 113, such that there is an electrical connection with the contact pads 124 when the metalized conformal shield 110 is applied to the circuit substrate 120. The electrical connection between the metallic layer 116 and the contact pads 124 electrically couples the metalized conformal shield 110 to the circuit substrate 120. Accordingly, in some embodiments, the metallic layer 116 may be applied (partially or entirely) while the conformal shield 113 is in the cast 420. In other embodiments, the conformal shield 113 may be removed from the cast 420 and then have the metallic layer 116 applied (partially or entirely) thereon to form the metalized conformal shield 110.

The metallic layer 116 may be made of an electrically conductive metal (e.g., copper, silver, nickel, etc.) to provide RF and EM shielding to the shielded circuit 100. In some embodiments, the metallic layer 116 may be formed of multiple layers. The metallic layer 116 may be applied on the conformal shield 113 via metal deposition or any other suitable method. For instance, the metallic layer 116 may be applied (but is not limited to) via a sputtering or evaporative coating process, electroless plating process, spray painting with metallic paint, silver-paste printing, and/or the like. In particular embodiments, the metallic layer 116 is deposited on the conformal shield 113 such that the metallic layer 116 has at least a minimal thickness (e.g., 1-5 μm) to provide uniform and complete metal coverage. In some embodiments, a thickness of the metallic layer 116 is less than a thickness of the release layer 111.

After forming the metalized conformal shield 110, at block B550, the metalized conformal shield 110 may be removed from the cast 420 (if not already removed as the conformal shield 113 and then coated with the metallic layer 116 to form the metalized conformal shield 110). As discussed, the release layer 111 may facilitate removal of the metalized conformal shield 110 from the cast 420. Accordingly, the metalized conformal shield 110 may be applied to the circuit substrate 120 by placing the metalized conformal shield 110 over the circuit components 130 and the circuit substrate 120 to form the shielded circuit 100 (e.g., block B330), for example, as shown in FIG. 2.

The method B500 described in FIG. 5A above may be performed by various hardware and/or software component(s) and/or module(s) corresponding to the means-plus-function blocks B500′ illustrated in FIG. 5B. In other words, one or more of blocks B510 through B550 illustrated in FIG. 5A may correspond to one or more of means-plus-function blocks B510′ through B550′ illustrated in FIG. 5B.

In various embodiments, a release layer (e.g., 111) is provided between the insulating layer 112 and the surface 425 of the cast 420 to facilitate removal of the metalized conformal shield 110 (or the conformal shield 113). In such embodiments, the release layer 111 compensates for any manufacturing differences (that are within specified tolerances) among circuit substrates and/or circuit components. In other embodiments, such a layer may be omitted. In such embodiments, for instance, a cast (e.g., 620 in FIG. 6) may be adapted to allow removal of the metalized conformal shield 110 from the cast with minimal or no adhesion of the metalized conformal shield 110 to the surface of the cast. For example, the cast may be formed of a non-adherable material (or otherwise be formed of a material having sufficiently low adhesion to the metalized conformal shield 110), such as stainless steel or the like, to allow removal of the metalized conformal shield 110 (or the conformal shield 113). As another example, a coating, such as a spray coating, of minimal thickness (e.g., less than 2 um) may be applied to the surface 425 of the cast 420 (or 620) to facilitate removal of the metalized conformal shield 110 from the cast 420.

With reference to FIGS. 1-3B and 5A-6D, in embodiments in which the cast is adapted to allow removal of the metalized conformal shield 110 (or the conformal shield 113), the cast, such as cast 620, may be formed to compensate for manufacturing differences. The cast 620 includes portions 630a-630 that correspond to the circuit components 130a-130d, respectively. For instance, the cast 620 may be formed to compensate for a tolerance range (along an x-, y-, and/or z-axis) for the position and/or size of one or one more of the circuit components 130 (e.g., FIG. 6A). For example, with respect to the circuit component 130d, the corresponding portion 630d may be sized to account for dimensions of the circuit component 130d and a tolerance range TR1 (shown as (TR1)/2 on each side of the portion 630d) along an x-axis (width) of the corresponding portion 630d, a tolerance range TR2 along a z-axis (height) of the portion 630d, and a tolerance range TR3 (not shown) along a y-axis (length) of the portion 630d.

The tolerance ranges TR1-TR3 may be the same as each other (e.g., 5 μm). In other embodiments, one or more of the tolerance ranges TR1-TR3 may be different from the other tolerance ranges. The tolerance ranges for a given circuit component (e.g., 130d) may be the same as the other circuit components (e.g., 130a-130c). In other embodiments, the tolerance ranges for a given circuit component may be different from the tolerance ranges of the other circuit components.

Accordingly, a metalized conformal shield 110′ (which may correspond to the metalized conformal shield 110) may be formed using the cast 620, for example, in a manner similar to blocks B520-550 or the like. For instance, at block B520, the insulating layer 112 may be deposited over a surface 625 of the cast 620 to form a conformal shield 113. A maximum thickness 113t′ of the conformal shield 113 may be substantially equal to a height 630h of the portion 630d (which corresponds to a maximum height of a tallest circuit component 130d that would be within the specified tolerance range for such component) (e.g., FIGS. 6B-6D). Then the plurality of openings 114 may be formed, for example as described with respect to block B530. The metallic layer 116 may be deposited over the conformal shield 113 to form the metalized conformal shield 110′, for example as described with respect to block B540. Then the metalized conformal shield 110′ may be removed from the cast 620, for example as described with respect to block B550. In other embodiments, the metalized conformal shield 110′ may be prepared in any suitable manner, such as described in (but not limited to) the disclosure.

With reference to FIGS. 1-6D, in some embodiments, a cast (e.g., 420) is formed from the assembled circuit (PCBA) 125 (i.e., from a physical version of the assembled circuit 125). For example, an imprint of the assembled circuit 125 may be made, and the imprint may be used to form the cast 420 corresponding to the assembled circuit 125. In other embodiments, the cast (e.g., 620) may be formed from specifications (e.g., from a CAD file or the like) of the circuit substrate 120 and/or the circuit components 130. The specifications may be a basis for assembling a plurality of assembled circuits 125. Thus, the cast 620 may be prepared without a corresponding assembled circuit 125 (i.e., physical version of the assembled circuit 125). Metalized conformal shields 110 prepared using the cast 620 may be prepared at any suitable time (e.g., before or after) relative to assembly of an assembled circuit 125 based on the specifications. In such embodiments, the cast 620 may be formed to compensate for any manufacturing differences among the plurality of assembled circuits 125.

In various embodiments, the same metalized conformal shield 110 is re-applied to the circuit substrate 120 and the circuit components 130 after readjusting one or more of the circuit components 130. In other embodiments, a new (second) metalized conformal shield 110 may be formed, for instance in a similar manner as the previous metalized conformal shield 110, for applying to the circuit substrate 120 and the circuit components 130 after readjusting one or more of the circuit components 130.

It is understood that the specific order or hierarchy of steps in the processes disclosed is an example of exemplary approaches. Based upon design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A method for manufacturing a removable metalized conformal shield for a circuit substrate having at least one circuit component, the method comprising:
forming a cast representing the circuit substrate having the at least one circuit component;
preparing a metalized conformal shield using the cast;
applying the metalized conformal shield to the circuit substrate;
measuring an output of the circuit component of the circuit substrate;
removing the metalized conformal shield from the circuit substrate; and
adjusting the circuit component based on the measured output.

2. The method of claim 1, the method further comprising:
re-applying the metalized conformal shield to the circuit substrate after adjusting the circuit component based on the measured output.

3. The method of claim 2, wherein after re-applying the metalized conformal shield, the method further comprising:
re-measuring the output of the circuit component of the circuit substrate;
re-removing the metalized conformal shield from the circuit substrate; and
re-adjusting the circuit component based on the measured output.

4. The method of claim 1, the method further comprising:
adjusting the circuit component of the circuit substrate to provide a specified output before applying the metalized conformal shield to the circuit substrate.

5. The method of claim 4, wherein, after removing the metalized conformal shield, the circuit component is adjusted based on the measured output and the specified output.

6. The method of claim 4, wherein the measured output corresponds to the specified output.

7. The method of claim 1, wherein the metalized conformal shield comprises a conformal shield made of an insulating layer and a metallic layer disposed over the conformal shield.

8. The method of claim 7, wherein the metallic layer is electrically coupled with contacts of the circuit substrate when the metalized conformal shield is applied to the circuit substrate.

9. The method of claim 1, wherein preparing a metalized conformal shield using the cast comprises:
depositing a release layer on a surface of the cast;
depositing an insulating layer over the release layer to form a conformal shield; and
depositing a metallic layer over the conformal shield to form the metalized conformal shield.

10. The method of claim 1, wherein preparing a metalized conformal shield using the cast comprises:
depositing an insulating layer over a surface of the cast to form a conformal shield; and
depositing a metallic layer over the conformal shield to form the metalized conformal shield.

11. The method of claim 1, wherein the circuit substrate having the at least one circuit component comprises a printed circuit board (PCB).

12. The method of claim 1, wherein forming a cast representing the circuit substrate having the at least one circuit component comprises:
assembling the at least one circuit component on the circuit substrate to provide an assembled circuit; and
forming a cast based on the assembled circuit.

13. The method of claim 1, wherein forming a cast representing the circuit substrate having the at least one circuit component comprises:
forming a cast representing the circuit substrate having the at least one circuit component based on specifications of the circuit substrate and the least one circuit component.

14. The method of claim 13, wherein forming a cast representing the circuit substrate having the at least one circuit component further comprises:
assembling the at least one circuit component on the circuit substrate to provide an assembled circuit; and
wherein the metalized conformal shield is prepared using the cast before the assembled circuit is provided

15. The method of claim 1, the method further comprising:
preparing a second metalized conformal shield using the cast; and
applying the second metalized conformal shield to the circuit substrate after adjusting the circuit component based on the measured output.

16. The method of claim 15, wherein after applying the second metalized conformal shield, the method further comprising:
re-measuring the output of the circuit component of the circuit substrate;
removing the second metalized conformal shield from the circuit substrate; and
re-adjusting the circuit component based on the measured output.

17. An apparatus for manufacturing a removable metalized conformal shield for a circuit substrate having at least one circuit component, the apparatus comprising:
means for forming a cast representing the circuit substrate having the at least one circuit component;
mean for preparing a metalized conformal shield using the cast;
means for applying the metalized conformal shield to the circuit substrate;
means for measuring an output of the circuit component of the circuit substrate;
means for removing the metalized conformal shield from the circuit substrate; and
means for adjusting the circuit component based on the measured output.

18. A method for manufacturing a removable metalized conformal shield for a circuit substrate having at least one circuit component, the method comprising:
forming a cast representing the circuit substrate having the at least one circuit component;
depositing an insulating layer over a surface of the cast to form a conformal shield; and
depositing a metallic layer over the conformal shield to form the metalized conformal shield.

19. The method of claim 18, the method further comprising:
removing the metalized conformal shield from the surface of the cast.

20. The method of claim 18, wherein the cast is formed of a material that does not adhere to the insulating layer.

21. The method of claim 18, wherein the cast is formed of a material comprising stainless steel.

22. The method of claim 18, wherein the cast is formed to compensate for a tolerance range of each circuit component of the at least one circuit component.

23. The method of claim 18, the method further comprising:
depositing a release layer over the surface of the cast;
wherein the insulating layer is deposited over the release layer to form the conformal shield.

24. The method of claim 23, the method further comprising:
removing the metalized conformal shield from the release layer on the surface of the cast.

25. The method of claim 23, the method further comprising:
removing the conformal shield from the release layer on the surface of the cast before the metallic layer is deposited over the conformal shield to form the metalized conformal shield.

26. The method of claim 23, wherein a thickness of the metallic layer is greater than a thickness of the release layer.

27. The method of claim 18, wherein a maximum thickness of the conformal shield is substantially equal to a height of a tallest circuit component of the at least one circuit component from a surface of the circuit substrate.

28. The method of claim 18, wherein a top surface of the conformal shield is flush with a top surface of a tallest circuit component of the at least one circuit component.

29. The method of claim 18, the method further comprising:
removing the conformal shield from the surface of the cast before the metallic layer is deposited over the conformal shield to form the metalized conformal shield.

30. The method of claim 18, wherein the metallic layer is electrically coupled with contacts of the circuit substrate when the metalized conformal shield is applied to the circuit substrate.

31. The method of claim 18, the method further comprising:
forming a plurality of openings in the conformal shield at one or more specified areas, the specified areas corresponding to contact pads on the circuit substrate.

32. The method of claim 31, wherein forming the plurality of openings in the conformal shield comprises ablating the insulating layer of the conformal shield at the specified areas.

33. The method of claim 31, wherein forming the plurality of openings in the conformal shield comprises:
applying a mask layer over portions of the release layer before depositing the insulating layer, the portions corresponding to the contact pads on the circuit substrate; and
removing the masking layer after depositing the insulating layer.

34. The method of claim 31, the method further comprising:
depositing at least some of the metallic layer in the plurality of openings in the conformal shield to electrically couple with the contact pads of the circuit substrate when the metalized conformal shield is applied to the circuit substrate.

35. The method of claim 34, wherein at least one of the plurality of openings in which the at least some metallic layer is deposited corresponds to one of the contact pads provided between at least two of the circuit components.
